(19) United States
(12) Patent Application Publication
(10) Pub. No.: US 2012/0225206 A1
(43) Pub. Date: Sep. 6, 2012

(54) Apparatus and Process for Atomic Layer Deposition

(75) Inventor: Joseph Yudovsky, Campbell, CA (US)

(73) Assignee: Applied Materials, Inc., Santa Clara, CA (US)

(21) Appl. No.: 13/037,430

(22) Filed: Mar. 1, 2011

(51) Int. Cl. C23C 16/458; C23C 16/455

(52) U.S. Cl. 427/255.5; 118/715; 118/728; 427/248.1

(57) ABSTRACT

Provided are atomic layer deposition apparatus and methods including a gas cushion plate comprising a plurality of openings configured to create a gas cushion adjacent the gas cushion plate so that a substrate can be moved through a processing chamber.

### BACKGROUND

Embodiments of the invention generally relate to an apparatus and a method for depositing materials. More specifically, embodiments of the invention are directed to an atomic layer deposition chamber having a gas cushion plate for creating a gas cushion capable of moving a substrate.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

Substrates are moved through the processing region by use of shuttles, susceptors and conveyor systems. These include many moving parts which can wear out and require maintenance. Therefore, there is an ongoing need in the art for improved apparatuses and methods of moving substrates through a process chamber.

### SUMMARY

Embodiments of the invention are directed to atomic layer deposition systems comprising a processing chamber configured to deposit material on a substrate. A gas distribution plate for facing a first surface of the substrate is located within the processing chamber. A gas cushion plate is positioned to face a second surface of the substrate. The gas cushion plate comprises a plurality of openings configured to create a gas cushion between the gas cushion plate and the substrate so that the substrate does not contact the gas cushion plate and to move the substrate through the processing chamber. The deposition system of specific embodiments includes at least one load lock chamber connected to the processing chamber.

In detailed embodiments, the gas cushion plate is below the gas distribution plate and the gas cushion plate creates a gas cushion above the gas cushion plate. In some embodiments, the gas cushion plate is above the gas distribution plate and the gas cushion plate creates a gas cushion below the gas cushion plate.

Some embodiments of the deposition system further comprise a susceptor having a top surface for carrying the substrate and a bottom surface for facing the gas cushion plate. The gas cushion plate being configured to create a gas cushion sufficient to elevate the susceptor and the substrate. In detailed embodiments, the top surface of the susceptor has a recess configured to accept the substrate. In specific embodiments, the first surface of the substrate is about level with the top surface of the susceptor.

In detailed embodiments, the plurality of openings in the gas cushion plate comprises a plurality of nozzles. In specific embodiments, the plurality of nozzles can be tilted to cause the substrate to move along the gas cushion.

Some embodiments of the deposition system further comprise a gas source in fluid communication with the gas cushion plate. The gas source is adapted to provide a gas flow of sufficient pressure so that the substrate above the gas cushion plate will not contact the gas cushion plate. In detailed embodiments, the gas source is an inert gas.

In specific embodiments, the gas distribution plate comprises a plurality of gas ports configured to transmit one or more gas streams to the substrate and a plurality of vacuum ports disposed between each gas port and configured to transmit the gas streams out of the processing chamber.

Additional embodiments of the invention are directed to methods of processing a substrate. A substrate having a first surface and a second surface is disposed in a processing chamber adjacent a gas distribution plate defining a process gap between the first surface of the substrate and the gas distribution plate. The second surface of the substrate is adjacent a gas cushion plate. A gas cushion is created between the substrate and the gas cushion plate. In detailed embodiments, the gas cushion is changed to cause the substrate to move along the gas cushion plate.

In one or more embodiments, the gas cushion is created above the gas cushion plate and is sufficient to cause the substrate to be elevated above the gas cushion plate.

In some embodiments, the substrate is disposed on a susceptor and the gas cushion is created beneath the susceptor. the gas cushion is sufficient to cause the susceptor and substrate to be elevated above the gas cushion plate. In detailed embodiments, the substrate is disposed in a recess in the susceptor so that the first surface of the substrate does not protrude above a top surface of the susceptor.

In some embodiments, the method further comprises tilting the processing chamber to cause the substrate to move within the processing chamber.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of an atomic layer deposition chamber according to one or more embodiments of the invention;

FIG. 2 shows a schematic view of an atomic layer deposition chamber according to one or more embodiments of the invention;

FIGS. 3A and 3B show gas cushion plates according to embodiments of the invention;

FIG. 4 shows a top view of an atomic layer deposition chamber in accordance with one or more embodiments of the invention;

FIGS. 5A and 5B show schematic views of an atomic layer deposition chamber in accordance with one or more embodiments of the invention; and

FIG. 6 shows a susceptor in accordance with one or more embodiments of the invention.

### DETAILED DESCRIPTION

Embodiments of the invention are directed to atomic layer deposition apparatus and methods which provide improved movement of substrates. Specific embodiments of the invention are directed to atomic layer deposition apparatuses (also called cyclical deposition) incorporating a gas cushion plate configured to create a gas cushion upon which substrates can float and/or directed.

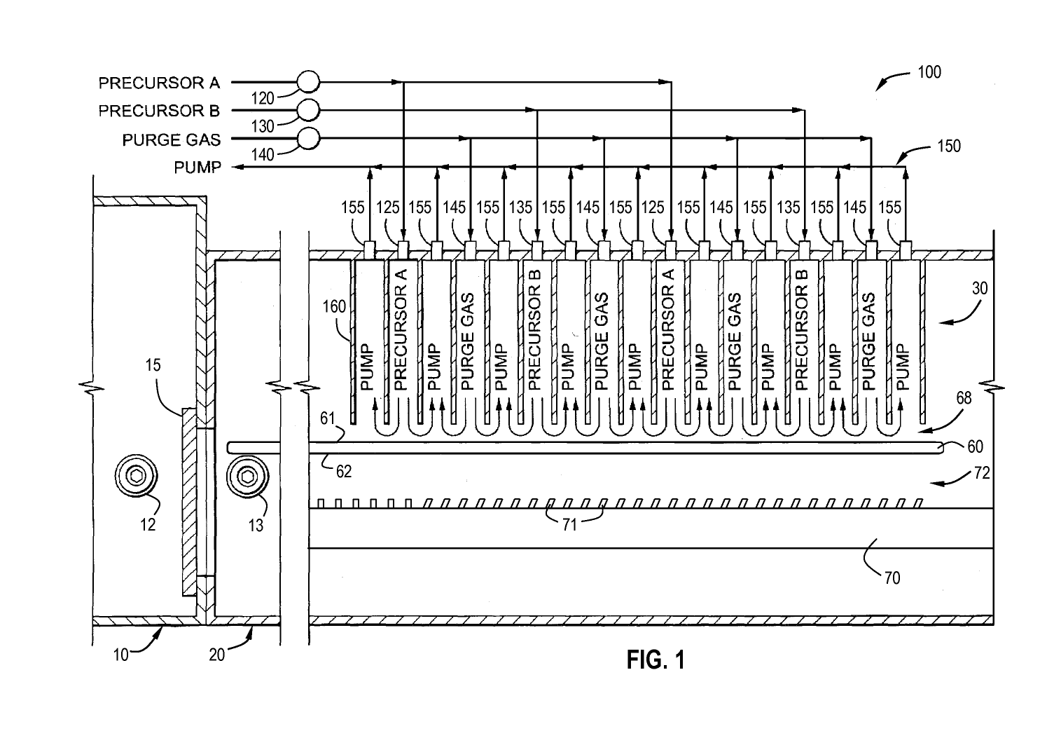

FIG. 1 is a schematic top view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The gas distribution plate 30 faces the first surface 61 of the substrate 60. A gas cushion plate 70 is positioned in the processing chamber 20 facing the second surface 62 of the substrate 60. The gas cushion plate 70 comprises a plurality of openings 71 configured to create a gas cushion 72 between the gas cushion plate 70 and the substrate 60.

FIG. 1 shows an upright orientation in which the gas distribution plate 30 is positioned above the substrate 60 and the gas cushion plate 70 is below the substrate 60. Here, the gas cushion plate 70 creates a gas cushion 72 beneath the substrate 60 that is capable of ensuring that the substrate 60 does not contact the gas cushion plate 70 or the gas distribution plate 30. The gas cushion 72 generated by the gas cushion plate 70 can be controlled to levitate the substrate 60 within the processing chamber and may also be capable of moving the substrate within the processing chamber. The gas pressure required in the gas cushion 72 can vary depending on many factors including, but not limited to, the size and weight of the substrate and the pressure of the gases from the gas distribution plate 30.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

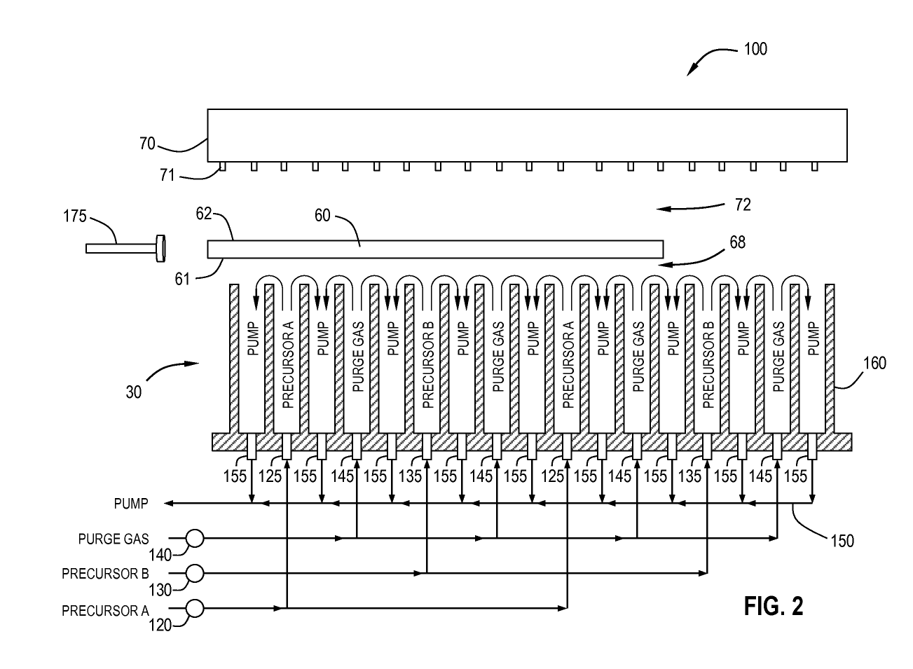

FIG. 2 shows an embodiment of the invention in an inverted orientation. The load lock chamber 10 and isolation valve 15 are omitted from FIG. 2, but it should be understood that these components may be included. Here, the gas distribution plate 30 is positioned beneath the substrate 60 and the gas cushion plate 70 is above the substrate. In this embodiments, the substrate 60 floats above the gas distribution plate 30 due to the pressure of gases from the gas distribution plate 30. The gas cushion plate 70 directs a gas flow toward the second surface 62, in this case the top surface, of the substrate. The gas cushion 72 may be controlled to maintain a uniform distance between the first surface 61 of the substrate 60 and the gas distribution plate 30. The gas cushion 72 may also be controlled to cause the substrate to move (e.g., translation or rotation) within the processing chamber.

At least one gas source 201 is in fluid communication with the gas cushion plate 70, or the plurality of openings 71. The at least one gas source 201 can be any suitable gas and in specific embodiments, the at least one gas source 201 is an inert gas. In detailed embodiments, the gas source is adapted to provide a gas flow of sufficient pressure so that the substrate above the gas cushion plate will not contact the gas cushion plate

The plurality of openings 71 in the gas cushion plate 70 can be configured in various ways. In some embodiments, the plurality of openings 71 are simple holes in and flush with the front surface of the gas cushion plate 70. In other embodiments, the plurality of openings 71 comprises a plurality of nozzles extending from the surface of the gas cushion plate, as shown in FIGS. 1 and 2. The nozzles can be tilted and rotated to affect the gas cushion 72, allowing the substrate 60 to move along the gas cushion 72. The nozzles can be controlled individually or in groups. In detailed embodiments, the nozzles can be tilted to an angle up to about 15 degrees. In various embodiments, the nozzles can be tilted to an angle up to about 10 degrees, or up to about 5 degrees. Tilting the nozzles may allow the gravity to drive the movement of the substrate 60 (or susceptor 65 as discussed later). The velocity of the substrate 60 can be controlled by changing the tilt angle of the nozzles. The direction of the substrate can be controlled by changing the angle and rotation of the nozzles.

In addition to nozzles, the plurality of openings 71 can comprise a series of channels formed in the gas cushion plate 70 surface. The channels can be perpendicular to the surface of the gas cushion plate 70 or can be tilted at an angle to drive the substrate 60 across the surface of the gas cushion plate. The channels can also comprise articulating sides so that the angle of the channel with respect to the surface of the gas cushion plate 70 can be changed dynamically.

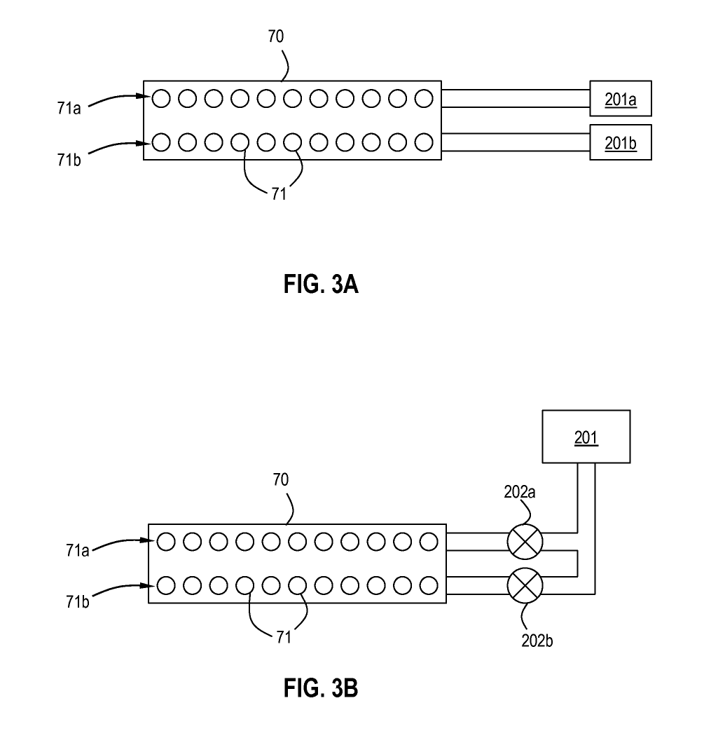

Additionally, the nozzles or openings can be isolated into zones with separate control and gas flow than adjacent zones. The control of the nozzles (e.g., rotation, tile and gas flow) can be controlled by a computer (not shown) to maximize the effectiveness of the gas cushion 72 to affect the stability of the substrate 60. FIGS. 3A and 3B show simplistic views of embodiments with zoned openings. FIG. 3A shows an embodiment of a gas cushion plate 70 having a plurality of openings 71 separated into a first zone 71a and a second zone 71b. The first zone 71a is connected to a first gas source 201a and the second zone 71b is connected to a second gas source 201b. Although not shown, it will be appreciated that the first gas source 201a and the second gas source 201b can be connected through at least one gas regulator or metering device.

FIG. 3B shows an alternate embodiment of a gas cushion plate 70 with the plurality of openings 71 separated into a first zone 71a and a second zone 71b. In this embodiment, a single gas source 201 is connected to a first regulator 202a and a second regulator 202b. The first regulator 202a is in flow communication with the first zone 71a of openings and the second regulator 202b is in flow communication with the second zone 71b of openings. While the embodiments of the FIGS. 3A and 3B are shown with two zones, it should be understood that the plurality of openings 71 in the gas cushion plate 70 can be separated into any number of zones and required. Additionally, the embodiments shown contain two rows of openings 71. This is merely for illustrative purposes and should not be taken as limiting the scope of the invention. The pattern of openings 71 in the gas cushion plate 70 can be used in any suitable arrangement.

In detailed embodiments, the angle and pressure of the gas flows making up the gas cushion 72 can be adjusted dynamically during processing. This can be accomplished using any configuration of openings 71, but may be of particular use with the nozzles shown in FIGS. 1 and 2. The individual nozzle tilt and pressure can be changed to cause the substrate 60 to move faster, get closer to the gas distribution plate 30, or rotate.

In embodiments having an upright orientation like that of FIG. 1, the pressure in the gas cushion 72 can be adjusted to ensure that the substrate 60, which in one or more embodiments is a rigid semiconductor substrate or wafer, floats above the gas cushion plate 70. The pressure required to float the substrate is at least about equal to the amount of pressure required to overcome gravity, but not so much as to uncontrollably lift the substrate. The pressure in the gas cushion 72 in detailed embodiments is at least about 5 torr greater than the pressure required to overcome gravity. The pressure in the gas cushion 72 in specific embodiments is at least about 5 torr greater than the pressure required to overcome the combined impact of gravity and the pressure generated by the gas distribution plate 30. The pressure of the gas cushion 72 can also vary from zone to zone so that the movement and stability of the substrate 60 can be controlled during processing.

The gas distribution plate 30 of some embodiments comprises a plurality of gas ports configured to transmit one or more gas streams to the substrate 60 and a plurality of vacuum ports disposed between each gas port and configured to transmit the gas streams out of the processing chamber 20. In the detailed embodiment of FIGS. 1 and 2, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 shown in FIGS. 1 and 2 include a plurality of partitions 160 disposed on the processing chamber 20 between each port. A lower portion of each partition extends close to substrate 60, for example, about 0.5 mm or greater from the substrate surface. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas cushion plates may be employed.

To operate the upright orientation shown in FIG. 1, a substrate 60 is delivered (e.g., by a robot) to the load lock chamber 10 and is placed on a system capable of moving the substrate 60. The system capable of moving the substrate 60 shown in FIG. 1 is a roller 12, but other mechanisms, including pushers or an extension of the gas cushion plate described, can be employed. The isolation valve 15 is opened to allow the substrate 60 to be disposed in the processing chamber 20. The roller 13 shown in FIG. 1 may be helpful in transitioning the substrate 60 from the load lock chamber 10 to the processing chamber 20, but is not necessary. The substrate 60, which in detailed embodiments is a rigid discreet substrate, has a first surface 61 and a second surface 62 and is positioned adjacent the gas distribution plate 30. A process gap 68 is defined between the first surface 61 of the substrate 60 and the gas distribution plate 30. The second surface 62 of the substrate 60 is adjacent the gas cushion plate 70. A gas cushion 72 is created beneath the substrate 60 to cause the substrate to move along the gas cushion plate 70. In specific embodiments, the gas cushion 72 has a pressure at least about 5 torr greater than the pressure required to lift the substrate.

As the substrate 60 moves through the processing chamber 20, a surface of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the substrate surface 110, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

Sufficient space is generally provided at the end of the processing chamber 20 so as to ensure complete exposure by the last gas port in the processing chamber 20. Once the substrate 60 reaches the end of the processing chamber 20 (i.e., the substrate surface 110 has completely been exposed to every gas port in the processing chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

In the inverted embodiment of FIG. 2, the substrate can be introduced to the processing chamber 20 in the same fashion as that of FIG. 1. Additionally, FIG. 2 shows a pusher 175 which may be useful for moving the substrate 60 from the load lock chamber 10 to the region between the gas cushion plate 70 and the gas distribution plate 30. While not necessary, it may be useful to decrease the pressure in the gas cushion 72 during loading and unloading of the substrate 60 to ensure that the leading/trailing edge of the substrate does not contact the gas distribution plate 30. This can be done by zoning the gas cushion or through dynamic control of the gas cushion. The gas cushion 72 in this embodiment is created above the substrate and causes the substrate to move across the chamber.

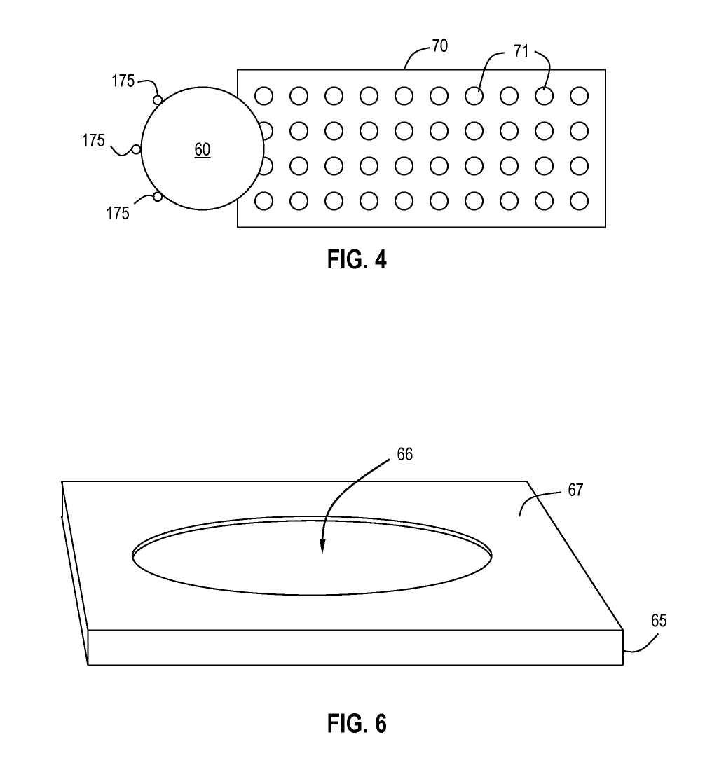

FIG. 4 shows a top view of another embodiment of the invention in the upright orientation of FIG. 1. Here the substrate 60 is pushed through the chamber by mechanical pushers 175. The pushers 175 are capable of moving the substrate across the chamber while the gas cushion 72 created by the gas cushion plate 70 supports the substrate. In detailed embodiments, the pushers provide substantially no lift to the substrate. As used in this specification and the appended claims, the term “substantially no lift” means that the pushers alone are not capable of elevating the substrate off of the gas cushion plate 70, or gas distribution plate 30. The pushers 175 can be independently movable or moved as a group. Additionally, the pushers can be move both along the plane of the gas distribution plate and perpendicular to such plane. The placement of the pushers may vary depending on use.

The pushers shown in FIG. 4 will be capable of moving the substrate from left-to-right, but not right-to left. Thus, a second set of pushers (not shown) may engage the substrate and push it from right-to-left. Additionally, the pushers may be able to be repositioned so that the substrate can be moved from right-to-left. In other embodiments, the pushers are distributed around the substrate is such a fashion that left and right movement of the substrate is possible without relocating the pushers. While three pushers 175 are shown in FIG. 4 is should be understood that any number of pushers 175 can be employed. In detailed embodiments the system includes at least two pushers. In specific embodiments, the system has three pushers or four pushers. The pushers can be made of any suitable material which can safely contact the substrate or can have a contact-safe coating. In detailed embodiments, the pushers are configured to push and/or rotate the substrate.

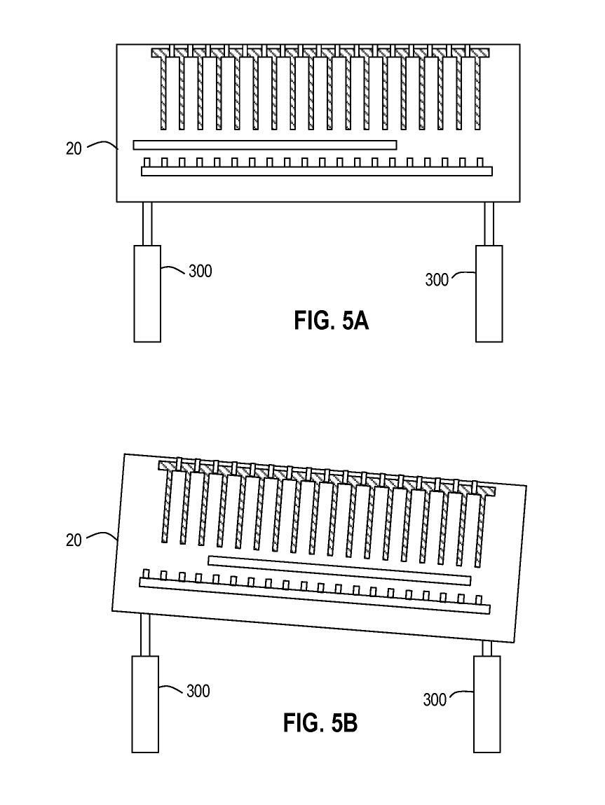

An alternate configuration of the system 100 is shown in FIGS. 5A and 5B. The processing chamber 20, at least, is mounted on extendable legs 300. In embodiments which use extendable legs 300 to drive the substrate movement, the plurality of openings 71 in the gas cushion plate 70 can remain in a fixed position, but may also be variable to include additional positional control for the substrate. In FIG. 5A, the legs 300 have equal heights so that a substrate within the chamber would remain in a substantially fixed position. In FIG. 5B the legs 300 are shown at different heights so that that processing chamber 20 is tilted. In this position, gravity will drive movement of the substrate 60 through the chamber. The legs 300 can be, for example, pneumatic or hydraulic and can be adjusted during processing to cause the substrate to move faster or slower, and back and forth within the chamber. The embodiment shown in FIGS. 5A and 5B are consistent with processing orientation shown in FIG. 1. However, it should be understood that this same configuration can be used with the inverted orientation of FIG. 2.

In yet another embodiment, the system 100 may be configured to process a plurality of substrates. In such an embodiment, the system 100 may include a second load lock chamber (disposed at an opposite end of the load lock chamber 10) and a plurality of substrate 60. The substrates 60 may be delivered to the load lock chamber 10 and retrieved from the second load lock chamber.

While the system shown in the figures has a single substrate, it should be understood that multiple substrate can be processed. For example, where the gas distribution plate 30 and the gas cushion plate 70 are large enough to process a substrate in a single pass, substrates can be queued so that multiple substrate are in the chamber at the same time.

In one or more embodiments, at least one radiant heat source (not shown) is positioned to heat the second side of the substrate. The radiant heat source is generally positioned on the opposite side of the gas cushion plate 70 from the substrate. In these embodiments, the gas cushion plate is made from a material which allows transmission of at least some of the light from the radiant heat source. For example, the gas cushion plate can be made from quartz, allowing radiant energy from a visible light source to pass through the plate and contact the back side of the substrate and cause an increase in the temperature of the substrate.

In some embodiments, the system 100 further includes a susceptor 65 for carrying the substrate 60. Generally, the susceptor 65 is a carrier which helps to form a uniform temperature across the substrate. The susceptor 65 is movable in both directions (left-to-right and right-to-left, relative to the arrangement of FIG. 1) between the load lock chamber 10 and the processing chamber 20. The susceptor has a top surface for carrying the substrate 60 and a second surface for facing the gas cushion plate 70. In these embodiments, the gas cushion plate 70 is configured to create a gas cushion 72 beneath the susceptor 65 sufficient to elevate the susceptor 65 and the substrate 60 above the gas cushion plate 70. The susceptor 65 may be a heated susceptor so that the substrate 60 may be heated for processing. As an example, the susceptor 65 may be heated by heat lamps, a heating plate, resistive coils, or other heating devices, disposed underneath the susceptor 65.

In still another embodiment, the top surface of the susceptor 65 includes a recess 66 configured to accept the substrate 60, as shown in FIG. 6. The susceptor 65 is generally thicker than the thickness of the substrate so that there is susceptor material beneath the substrate. In detailed embodiments, the recess 66 is configured such that when the substrate 60 is disposed inside the recess 66, the top surface of substrate 60 is level with the top surface 67 of the susceptor 65. Stated differently, the recess 66 of some embodiments is configured such that when a substrate 60 is disposed therein, the first surface 61 of the substrate 60 does not protrude above the top surface 67 of the susceptor 65.

When a susceptor 65 is included in the system, additional support may be needed to handle the weight of the susceptor 65. In detailed embodiments, the area of the gas cushion plate 70 is increased to ensure that the entire susceptor is supported by the gas cushion. In some embodiments, the system includes side supports which can be provide some support for the susceptor in addition to the gas cushion. In detailed embodiments, the substrate sits in a through hole in the susceptor, which allows the susceptor to act as a pusher 175.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. An atomic layer deposition system, comprising:
a processing chamber configured to deposit material on a substrate;
a gas distribution plate positioned to face a first surface of the substrate when located within the processing chamber; and
a gas cushion plate positioned to face a second surface of the substrate, the gas cushion plate comprising a plurality of openings that creates a gas cushion between the gas cushion plate and the substrate so that the substrate does not contact the gas cushion plate and to move the substrate through the processing chamber.

2. The atomic layer deposition system of claim 1, wherein the gas cushion plate is below the gas distribution plate and the gas cushion plate creates a gas cushion above the gas cushion plate.

3. The atomic layer deposition system of claim 1, wherein the gas cushion plate is above the gas distribution plate and the gas cushion plate creates a gas cushion below the gas cushion plate.

4. The atomic layer deposition system of claim 1, further comprising a susceptor having a top surface that carries the substrate and a bottom surface, the gas cushion plate creates a gas cushion between the gas cushion plate and the bottom surface of the susceptor that elevates the susceptor and the substrate.

5. The atomic layer deposition system of claim 4, wherein the top surface of the susceptor has a recess that accepts the substrate.

6. The atomic layer deposition system of claim 5, wherein the first surface of the substrate is about level with the top surface of the susceptor.

7. The atomic layer deposition system of claim 1, wherein the plurality of openings comprise a plurality of nozzles.

8. The atomic layer deposition system of claim 7, wherein the plurality of nozzles can be tilted to cause the substrate to move along the gas cushion.

9. The atomic layer deposition system of claim 1, further comprising a gas source in fluid communication with the gas cushion plate, the gas source that provides a gas flow of sufficient pressure so that the substrate above the gas cushion plate will not contact the gas cushion plate.

10. The atomic layer deposition system of claim 9, wherein the gas source is an inert gas.

11. The atomic layer deposition system of claim 1, further comprising at least one load lock chamber connected to the processing chamber.

12. The atomic layer deposition system of claim 1, wherein the gas distribution plate comprises a plurality of gas ports that transmit one or more gas streams to the substrate and a plurality of vacuum ports disposed between the gas ports and that transmit the gas streams out of the processing chamber.

13. A method of processing a substrate comprising:
disposing the substrate having a first surface and a second surface in a processing chamber adjacent a gas distribution plate defining a process gap between the first surface of the substrate and the gas distribution plate, the second surface of the substrate being adjacent a gas cushion plate; and
creating a gas cushion between the substrate and the gas cushion plate.

14. The method of claim 13, wherein the gas cushion is created above the gas cushion plate and causes the substrate to be elevated above the gas cushion plate.

15. The method of claim 13, further comprising changing the gas cushion to cause the substrate to move along the gas cushion plate.

16. The method of claim 13, wherein the substrate is disposed on a susceptor and the gas cushion is created beneath the susceptor, the gas cushion causing the susceptor and substrate to be elevated above the gas cushion plate.

17. The method of claim 16, wherein the substrate is disposed in a recess in the susceptor so that the first surface of the substrate does not protrude above a top surface of the susceptor.

18. The method of claim 13, further comprising tilting the processing chamber to cause the substrate to move within the processing chamber.
